(19) United States
(12) Patent Application Publication
(10) Pub. No.: US 2025/0154638 A1
(43) Pub. Date: May 15, 2025

(54) PROCESS FOR DECORATING WATCH COMPONENTS

(71) Applicant: The Swatch Group Reseach and Development Ltd., Marin (CH)

(72) Inventors: Vladislav SPASSOV, Praz (CH); Loïc Curchod, Lausanne (CH); Mina Moradi, Olten (CH); Simon Springer, Berne (CH)

(73) Assignee: The Swatch Group Reseach and Development Ltd., Marin (CH)

(21) Appl. No.: 18/905,296

(22) Filed: Oct. 3, 2024

(30) Foreign Application Priority Data
Nov. 10, 2023 (EP) 23209154.6

(51) Int. Cl. C23C 14/00; C23C 14/02; C23C 14/14; G04D 3/00

(52) U.S. Cl. CPC C23C 14/0015; C23C 14/024; C23C 14/14; G04D 3/0074

(57) ABSTRACT

A process of decorating a watch component with a white coating. The process includes preparing the watch component, depositing in a deposition chamber a metal adhesion layer over the entire watch component via physical vapor deposition, depositing an aluminum diffusing layer over the entire component under a flow of a reactive gas so that the aluminum layer is deposited in the form of a faceted crystalline structure, via physical vapor deposition, reducing or stopping the flow of the reactive gas when the diffusing layer has reached the desired thickness in order to terminate the layer with a thin layer of pure aluminum, and depositing a transparent protective layer via atomic thin-film deposition.

### CROSS REFERENCE TO RELATED APPLICATION

This application claims priority from European Patent Application No. 23209154.6, filed Nov. 10, 2023, which is hereby incorporated by reference in its entirety into this application.

### TECHNICAL FIELD OF THE INVENTION

The invention relates to a coating having a white surface obtained by superimposing layers deposited by PVD and ALD. The invention also relates to watch components having such a white surface.

### Technological Background

The watch industry is constantly seeking new solutions in terms of color and appearance. White timepieces, such as dials, are often obtained by the use of mother-of-pearl or the application of enamel.

The surface of noble metals such as silver, platinum, palladium and rhodium gives a brilliant white appearance. Such an appearance can also be achieved by galvanic deposition of these metals. However, they reflect light specularly, giving the surface of the article a brilliant metallic sheen. By carefully parameterizing the galvanic deposition process, the specular sheen of this coating is then reduced to matte white.

Vacuum Physical Vapor Deposition (PVD) techniques, such as cathodic sputtering, can be used to produce thin coatings with predefined properties on substrates of various kinds and with complex (three-dimensional) geometries.

Many other natural substances have a white color. Examples include pigments made from micro-particles of mineral substances such as titanium or aluminum oxide. These particles reflect light diffusely. These pigments are deposited as paints, lacquers or enamels on the surface of the articles.

However, pigment-based white coatings do not provide a sufficient and satisfactory decorative quality. This is because they don't preserve the surface finish of the substrate, nor do they preserve the detail of the decorations accurately. Also, prior art galvanic coatings have a matte appearance and are relatively brittle.

There is therefore a need for a white coating that preserves the surface finish of the substrate.

### SUMMARY OF THE INVENTION

One of the aims of the invention is notably to overcome the various drawbacks of prior art processes.

More precisely, one objective of the invention is to propose a process for manufacturing a white “porcelain” coating that retains the surface finish of the polished, matte, sunrayed or otherwise decorated substrate, as well as a watch component with a surface coated with a thin layer of white color obtained by this process.

To this end, the invention relates to a process for decorating a watch component with a white coating comprising the following steps:
preparing the watch component and installing said component in a deposition chamber;
depositing a metal adhesion layer over the entire watch component by physical vapor deposition;
depositing an aluminum diffusing layer over the entire component, under a flow of a reactive gas, such that the deposited layer contains between 0.5 atom % and 10 atom % of this gas, so that the aluminum layer crystallizes in the form of a faceted crystalline structure, via physical vapor deposition;
reducing or cutting off the flow of reactive gas when the diffusing layer has reached the desired thickness in order to finish the stack with a thin layer of pure aluminum to maximize the reflectivity of the resulting stack;
depositing a transparent protective layer using the ALD method.

In accordance with further advantageous variants of the invention:
the adhesion layer is a metal layer or a metal alloy which may be selected from: aluminum, titanium, titanium aluminide or chromium;
the adhesion layer has a thickness of between 30 nm and 100 nm, preferably 50 nm;
the process comprises an additional step of depositing a dielectric layer after the adhesion layer has been deposited;
the dielectric layer has a thickness of between 500 nm and 2000 nm, preferably 1000 nm;
the dielectric layer can be an aluminum, titanium or silicon nitride, oxide or oxynitride;
the diffusing layer has a thickness of between 300 nm and 6000 nm, preferably between 1000 nm and 2000 nm, more preferably 1500 nm;
the final layer of pure aluminum has a thickness of between 50 nm and 400 nm, preferably 200 nm;
the protective layer has a thickness of between 0.5 nm and 20 nm, preferably 2 nm;
the protective layer can be selected from the following materials: titanium dioxide, aluminum oxide, silicon dioxide, silicon nitride;
the preparation of the watch component prior to the deposition of the above-mentioned layers comprises a washing step;
the watch component has decorations and/or a surface finish;
The reactive gas during deposition of the diffusing layer is oxygen or nitrogen.

The invention also relates to a watch component having a white coating obtained using the process described herein.

### BRIEF DESCRIPTION OF THE FIGURES

Further features and advantages of the invention will become apparent from reading the following detailed description, given by way of example by no means restrictive, with reference to the appended drawings wherein:

FIG. 1 schematically shows a substrate with a white coating obtained using the process of the invention;

FIG. 2 shows a schematic representation of the steps in the process according to the invention.

### DETAILED DESCRIPTION OF THE INVENTION

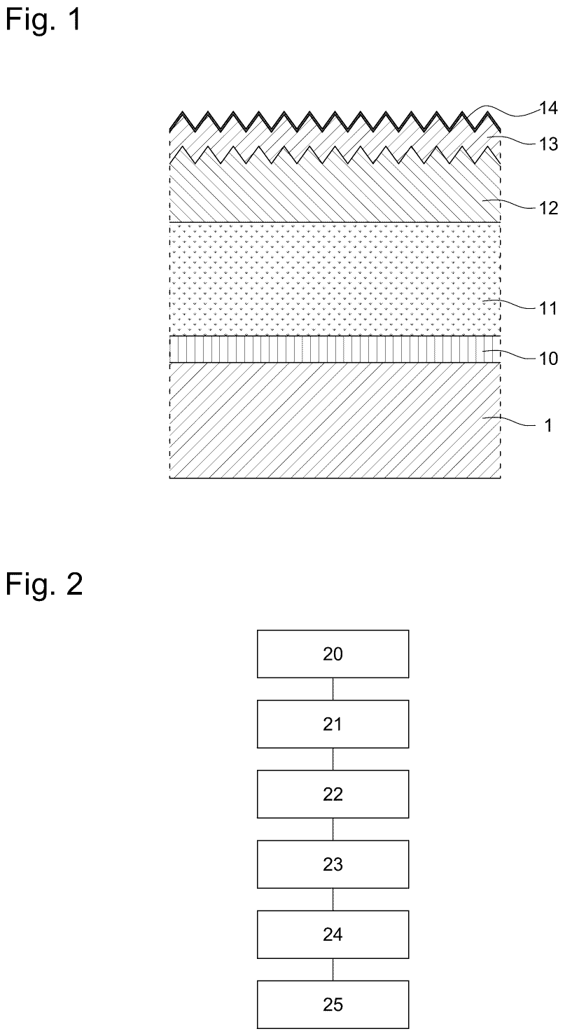

FIG. 1 shows a schematic representation of the stack of layers obtained according to the process of the invention.

According to one aspect of the invention, the deposition of coatings imparting a porcelain white color to the surface of the decorative article is carried out by a succession of PVD and ALD deposits.

Preferably, an enclosure equipped with a magnetron-type sputtering system is used for the purpose of the invention. Said spraying system comprises at least one aluminum spraying target and gas injection lines for creating a controlled reactive or inert atmosphere inside the enclosure. The operation of this spray device is described in the scientific and technical literature, is known to the person skilled in the art and will only be repeated herein in outline.

According to the invention, the white-colored surface is composed of a coating comprising at least four layers 10, 12, 13 and 14 on a substrate 1. In order to achieve the desired structure of layer 12, on most substrates a fifth layer, this being the dielectric layer 11, is required.

The process according to the invention comprises a first step 20 during which the substrate, herein the watch component, is cleaned by in-situ plasma in the deposition chamber by polarization of the substrate holder or by any other method known to the person skilled in the art.

The process comprises a second step 21 for depositing a first layer 10 on the substrate 1, referred to as the adhesion layer. The adhesion layer 10 may for example consist of aluminum deposited by spraying an aluminum source in a neutral atmosphere, that is, without the addition of reactive gas. The adhesion layer may also be made of titanium, titanium aluminide or else chromium and is typically between 30 nm and 100 nm thick, preferably 50 nm.

The process comprises an optional step 22 in which a dielectric layer 11 is deposited on the adhesion layer. The thickness of this layer is between 500 nm and 2000 nm, preferably 1000 nm, and is composed of a nitride, oxide or oxynitride of aluminum, titanium or silicon. This layer is used for preferential nucleation of the layer 12 deposited in step 23.

The third step 23 comprises depositing a second layer 12. During this step, the cathode equipped with the aluminum target is used and a reactive gas, such as oxygen or nitrogen, is introduced into the chamber and maintained at a rate so as to obtain a layer of aluminum doped with 0.5 to 10 atom % reactive gas, known as the diffusing layer 12. The diffusing layer 12 has a thickness of between 300 nm and 6000 nm, preferably between 1000 nm and 2000 nm, preferably 1500 nm.

The aim of this third step is to influence the deposition of aluminum atoms with the reactive gas to obtain a layer of aluminum oxide (or aluminum nitride in the case of nitrogen) with a faceted crystalline structure. Thanks to its faceted crystalline structure, such a layer provides a diffusing effect on incident light.

In a fourth step 24, without quenching the cathode with the aluminum target, the reactive gas flow is stopped completely or progressively reduced until it stops in order to finish the deposition of the diffusing layer 12 with a pure aluminum layer 13, thus without reactive gas doping, when the desired thickness of the oxygen-doped layer is reached. The final layer of pure aluminum 13 has a thickness of between 50 nm and 400 nm, preferably 200 nm.

Finally, in a fifth step 25, once the desired thickness of the pure aluminum layer 13 has been reached, a transparent protective layer 14 is deposited, preferably by an ALD deposition method. The protective layer 14 is composed of one of the following materials: titanium dioxide, aluminum oxide, silicon dioxide or silicon nitride.

Thus, the diffusing layer 12 covered by the pure aluminum layer 13 effectively reflects white light diffusely, imparting a white color to the treated substrate while retaining the details of the surface finish and decoration thereof.

First embodiment of the process according to the invention:
the substrate 1 is plasma-cleaned in-situ in the deposition chamber by polarization of the substrate holder;
an aluminum adhesion layer is deposited using an aluminum target without the addition of reactive gas;
then, without extinguishing the cathode, oxygen is introduced into the deposition chamber, the flow of oxygen is selected and maintained such that a layer of aluminum oxide is deposited with a composition substantially close to that of Al₂O₃;
then, without extinguishing the cathode, the flow of oxygen is reduced and maintained at a value that produces an oxygen-doped aluminum layer forming a diffusing faceted crystalline structure;
once the desired thickness of the oxygen-doped layer is reached, without extinguishing the cathode, the flow of oxygen is stopped completely in order to finish the deposition of the diffusing layer with pure aluminum, without oxygen doping;
once the desired thickness of the pure aluminum layer has been reached, the PVD deposition process is completed and a transparent protective layer is deposited using the ALD deposition method.

Second embodiment of the process according to the invention:
E the substrate 1 is plasma-cleaned in-situ in the deposition chamber by polarization of the substrate holder;
an aluminum adhesion layer is deposited using an aluminum target without the addition of reactive gas;
then, without extinguishing the cathode, a reactive gas is immediately introduced into the chamber, preferably nitrogen. The nitrogen flux is maintained at a value that produces a nitrogen-doped aluminum layer forming a diffusing crystalline structure;
once the desired thickness of the nitrogen-doped layer is reached, without extinguishing the cathode, the flow of nitrogen is gradually stopped in order to finish the deposition of the diffusing layer with pure aluminum, without nitrogen doping;
once the desired thickness of the pure aluminum layer has been reached, the PVD deposition process is completed and a transparent protective layer is deposited using the ALD deposition method.

The substrate, or watch component, has a polished, structured or decorated surface, for example an engraved, “perlage”, satin-finished, “côtes de Genève”, spiral, “guilloché”, sunrayed, carved surface, etc. The white decorative coating of the invention is sufficiently thin to allow the decoration to be clearly distinguished and to restore the surface condition of the underlying substrate. The result is a white, porcelain-like, decorated surface. The surface finish and topography of the substrate are preserved and perfectly perceptible/visible once the coating has been applied. Thus, a shiny substrate with “perlage” will retain its shiny appearance and the “perlage” will be visible. Similarly, a matte substrate with “côtes de Genève” will retain its matte appearance and the “côtes de Genève” will be perfectly visible.

The process of the invention makes it possible to deposit a white “porcelain” coating on all types of watch components to obtain particularly attractive decorative items. For example, internal components such as dials, hands, appliques, bridges, plates, barrels, oscillating weights, etc., can be white-coated using the process described herein. Moreover, the process according to the invention can also be applied to jewelry items.

Thus, it is possible to obtain a watch component having a porcelain-white appearance while retaining the surface finish and decorations of the component.

1. A process of decorating a watch component (1) with a white coating comprising the following steps:
preparing the watch component (1) and installing said component in a deposition enclosure;
depositing a metal adhesion layer (10) over the entire watch component by physical vapor deposition;
depositing a diffusing layer (12) of aluminum over the entire component, under a flow of reactive gas, the rate of reactive gas is maintained so as to obtain a layer of aluminum doped with 0.5 atom % to 10 atom % reactive gas, so that the aluminum layer crystallizes in the form of a faceted crystalline structure, via physical vapor deposition;
reducing or cutting off the flow of reactive gas when the diffusing layer has reached the desired thickness in order to terminate the diffusing layer (12) with a thin layer of pure aluminum (13); and
depositing a transparent protective layer (14) by atomic thin-film deposition.

2. The decorating process according to claim 1, wherein the adhesion layer (10) is a metal layer or a metal alloy selected from: aluminum, titanium, titanium aluminide or chromium.

3. The decorating process according to claim 1, wherein the adhesion layer (10) has a thickness of between 30 nm and 100 nm.

4. The decorating process according to claim 1, further comprising a step of depositing a dielectric layer (11) under a flow of oxygen or nitrogen after deposition of the adhesion layer.

5. The decorating process according to claim 4, wherein the dielectric layer (11) has a thickness of between 500 nm and 2000 nm.

6. The decorating process according to claim 4, wherein the dielectric layer (11) is a nitride, oxide or oxynitride of aluminum, titanium or silicon.

7. The decorating process according to claim 1, wherein the diffusing layer (12) has a thickness of between 300 nm and 6000 nm.

8. The decorating process according to claim 1, wherein the pure aluminum layer (13) has a thickness of between 50 nm and 400 nm.

9. The decorating process according to claim 1, wherein the protective layer (14) has a thickness of between 0.5 nm and 20 nm.

10. The decorating process according to claim 1, wherein the protective layer (14) is selected from the following materials: titanium dioxide, aluminum oxide, silicon dioxide, silicon nitride.

11. The decorating process according to claim 1, wherein the reactive gas used for the diffusing layer (11) is oxygen or nitrogen.

12. A watch component such as a dial, a hand, an applique, a bridge, a plate, an oscillating weight, a barrel, a clasp, with a white surface obtained by the process according to claim 1.
